(19) United States
(12) Patent Application Publication
(10) Pub. No.: US 2026/0082516 A1
(43) Pub. Date: Mar. 19, 2026

(54) HEAT SINK AND MANUFACTURING PROCESS

(71) Applicant: John Patton Wallis, Elgin, IL (US)

(72) Inventor: John Patton Wallis, Elgin, IL (US)

(21) Appl. No.: 19/327,755

(22) Filed: Sep. 12, 2025

Related U.S. Application Data
(60) Provisional application No. 63/693,886, filed on Sep. 12, 2024.

(51) Int. Cl. H05K 7/20; B23P 15/26

(52) U.S. Cl. CPC H05K 7/2039; B23P 15/26; B23P 2700/10

(57) ABSTRACT

Corrugated fin components and base plates are stamped from coil-fed sheet in progressive dies. The corrugated component is staked to a primary base plate and the primary base plate is staked to a secondary base plate by plastically deforming conic posts into mushroom-shaped heads, thereby mechanically joining components without loose fasteners or adhesives. The manufacturing line may include multiple punch presses, staking stations, and positioning fixtures arranged about a rotary table or along a conveyor. Pick-and-place robots load the parts, and a PLC coordinates stamping, staking, inspection/sorting, and packaging. Vent apertures can be pierced in the corrugated component to promote omni-directional airflow. The approach enables high fin density and increased surface area relative to die-cast or extruded designs, supporting reduced weight, lower material usage, and high-throughput production.

### CROSS-REFERENCE TO RELATED APPLICATION

The present application claims priority to and the benefit of US Provisional Application No. 63/693,886, filed Sep. 12, 2024, the contents of which are incorporated herein by reference and made a part hereof.

### BACKGROUND OF THE INVENTION

The present invention relates to thermal management systems, and more particularly to a method for manufacturing and assembling high-performance heat sinks using progressive metal stamping and automated assembly techniques.

Efficient thermal management is critical in modern electronic systems to ensure reliable operation and prevent overheating of components such as processors, power modules, and LEDs. Heat sinks are widely used as passive cooling devices that dissipate heat from these components into the surrounding environment. Conventional heat sinks are typically fabricated from thermally conductive materials such as aluminum or copper, which provide a balance between thermal performance, weight, and cost.

Various manufacturing techniques have been developed to produce heat sinks with different geometries and performance characteristics. Extrusion is one of the most common methods, wherein heated aluminum is forced through a die to create elongated profiles with integral fins. While extrusion is cost-effective and suitable for medium to large-scale production, it limits the complexity and density of fin structures. Die casting allows for more intricate geometries by injecting molten metal into a mold; however, this process often results in thicker fins and internal porosity, which can reduce thermal efficiency. Stamping techniques form fins from thin metal sheets that are subsequently stacked or bonded to a base, enabling low-profile designs but requiring additional assembly steps. Machining, such as CNC milling, provides high precision and customization but is generally expensive and time-consuming, making it less suitable for mass production. Advanced methods such as skiving or bonded-fin assembly enable high fin density and improved heat dissipation but at a higher manufacturing cost.

Surface treatments are commonly applied to enhance performance and durability. For example, aluminum heat sinks are often anodized to improve corrosion resistance and emissivity, while copper components may be nickel-plated to prevent oxidation. Despite these advancements, existing heat sink designs and manufacturing methods often involve trade-offs between thermal performance, weight, cost, and design flexibility, creating a need for improved solutions that address these limitations.

### SUMMARY OF THE INVENTION

The invention provides a process for manufacturing heat sinks by stamping corrugated fin components and base plates from coil stock using progressive dies, followed by automated staking and assembly. The process integrates programmable logic control (PLC) for synchronized operation of stamping presses, robotic handling, and packaging systems. This approach reduces manufacturing cost, weight, and material usage while improving thermal performance and enabling high-volume production.

In one aspect, a method for manufacturing a heat sink includes: progressively stamping one or more corrugated radiator components from coil-fed sheet; stamping a primary base plate and at least one secondary base plate; staking the corrugated radiator component to the primary base plate; staking the primary base plate to the secondary base plate; and ejecting, inspecting/sorting, and packaging compliant assemblies. Tooling may be positioned about a rotary index table or along a linear conveyor, with pick-and-place robots and positioning fixtures used to load and transport work-in-process. A PLC coordinates presses, robotics, and packaging actuators.

In another aspect, a heat sink includes a stamped corrugated radiator and stamped base plate(s) mechanically secured by mushroomed staking posts formed from conic posts in the base plate(s), without the need for loose fasteners or adhesives.

In yet another aspect, a manufacturing cell integrates multiple presses, transfer stations, robotic handlers, in-line inspection/sorting, and packaging, under the control of a PLC executing a process sequence for high-volume production.

As used herein and recognized by one of skill in the art, “Corrugation” or “corrugated radiator component” means a thin sheet formed into repeated alternating bends to increase surface area and promote convective heat transfer. “Staking” means a cold-forming mechanical joining process wherein a post (e.g., a conic post integral to a base plate) is plastically deformed to create a mushroom-shaped head that mechanically captures another component. “PLC” means a programmable logic controller configured to coordinate press strokes, indexing, robotic pick-and-place, inspection gates, and packaging actuators. “Coil stock” means continuous metal strip (e.g., aluminum or copper) supplied from a coil-fed system to a stamping press.

Additionally, one of skill in the art would recognize that In various embodiments, components are formed from aluminum (e.g., 1xxx, 3xxx, or 6xxx series) or copper (e.g., C110), optionally in an annealed or temper-adjusted condition to facilitate stamping and staking. The process supports hybrid constructions (e.g., copper radiator with aluminum base), with optional surface treatments such as anodizing (for aluminum) or nickel plating (for copper) to enhance corrosion resistance and emissivity.

### BRIEF DESCRIPTION OF THE DRAWINGS

In the accompanying figures, like elements are identified by like reference numerals among the several preferred embodiments of the present invention.

FIG. 1A-C is a schematic of a progressive stamping and automated assembly line showing coil-fed raw material, progressive forming of corrugated radiator components, base-plate stamping, and staking stations, culminating in inspection and packaging.

FIGS. 2A-2C depict two-piece heat sink side and end view.

FIGS 3A-3C depict a five-piece heat sink side and end views.

FIG. 4 is an exploded view with bill of materials for a multi-piece heat sink (e.g., 3-strand corrugation stamping, primary base plate, secondary base plate) (cf. page 4).

FIG. 5 is a flowchart of the ten-step process sequence described on page 4 (stamping, inspection/sorting, staking, transfer, ejection, PLC control, and packaging).

Other aspects and advantages of the present invention will become apparent upon consideration of the following detailed description, wherein similar structures have similar reference numerals.

### DETAILED DESCRIPTION OF THE PREFERRED EMBODIMENTS

The foregoing and other features and advantages of the invention will become more apparent from the following detailed description of an exemplary embodiment, read in conjunction with the accompanying drawings. The detailed description and drawings are merely illustrative of the invention rather than limiting, the scope of the invention being defined by the appended claims and equivalents thereof.

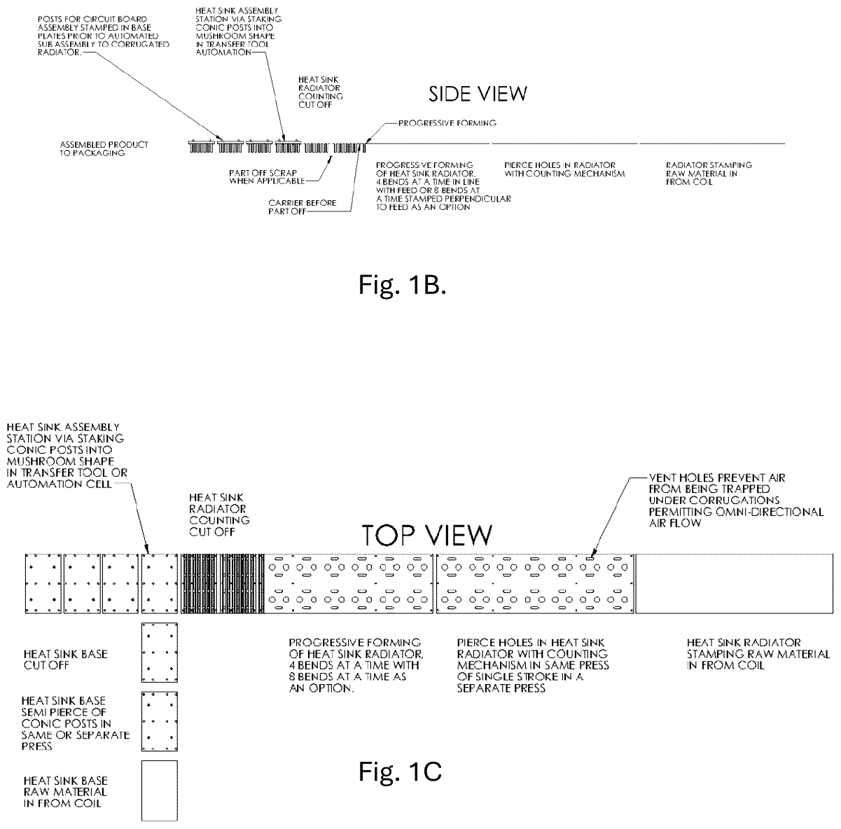

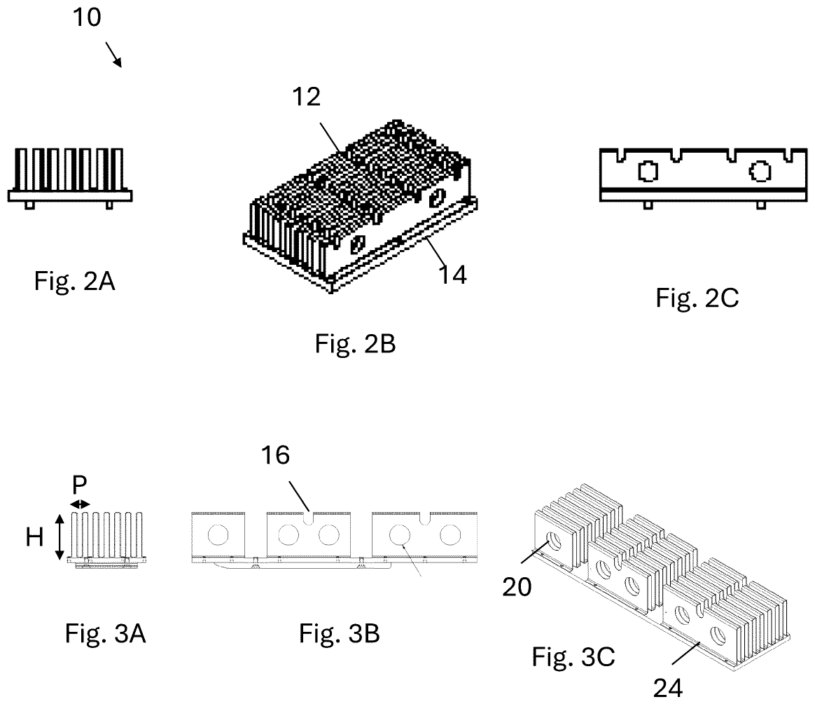

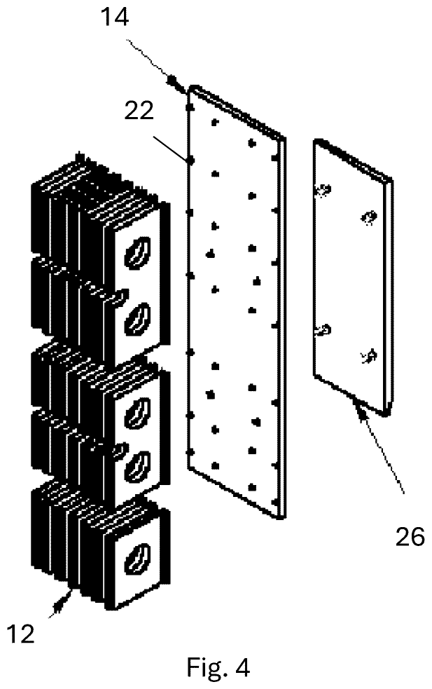

As shown in FIGS. 2A-2C and FIGS. 3A-3B the corrugated radiator heat sink 10 comprises a corrugated radiator component 12 and base plate 14. The corrugated radiator component may be formed by progressive bending in a punch press. The fin pitch P and fin height H are selectable; corrugation may be formed in-line with the material feed or perpendicular thereto. In some aspects, vent apertures can be pierced to prevent air entrapment beneath corrugations 16 and promote omni-directional airflow. Further, mounting apertures 18 and optional fluid-passage apertures 20 (for water pipes in active assemblies) may be pierced in-line. The base plate 14 in some aspects may be stamped from coil and include integral conic posts 22 (semi-pierced or formed) positioned to align with corresponding receptors or through-holes 24 in the corrugated radiator components 12 and/or secondary base plate 26. The optional secondary base plate 26 may be used to provide additional stiffness and stability to the base plate or provide additional heat dissipation options through additional materials or cutouts. As shown in FIGS. 3A-3C and FIG. 4, a heat sink 10 two or more corrugated radiator components.

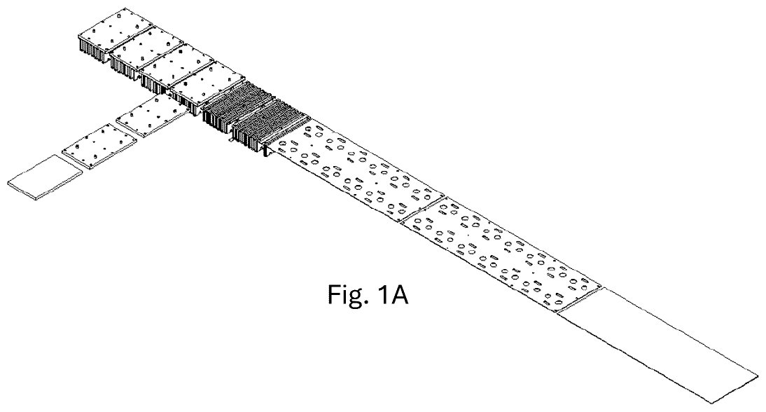

As schematically depicted in FIGS. 1A-1C, coil-fed strip enters progressive dies that (i) blank, pierce, and progressively bend the radiator components 12 and (ii) blank and form base plates 14, including post formation (e.g., semi-pierce to create conic posts). Radiator stampings 12 may be produced with 4 bends per stroke in-line with feed, or 8 bends per stroke perpendicular to feed, depending on die configuration and throughput goals.

Transfer from stamping to assembly may be performed manually or by pick-and-place robots to positioning fixtures arranged about a rotary indexing table or along a conveyor. The assembly sequence loads corrugation 12 first, followed by base plate(s) 14.

Staking stations deform the conic posts to mushroom heads, mechanically fixing the corrugation 12 to the primary base plate 14, and subsequently staking the primary base plate 14 to the secondary base plate 24. Ejection of the assembled heat sink 10 is followed by inspection and sorting, with compliant assemblies transferred to packaging and trays/cartons for shipping.

A PLC orchestrates press activation, robotics, indexing, inspection (e.g., optical counting mechanisms to verify apertures and bends), rejection gates, and packaging actuators.

Inspection may include: Part-count confirmation (e.g., aperture counting in the radiator), Presence/absence checks for corrugations and base plates at each station, Stake deformation depth/diameter verification, and Out-of-tolerance sorting.

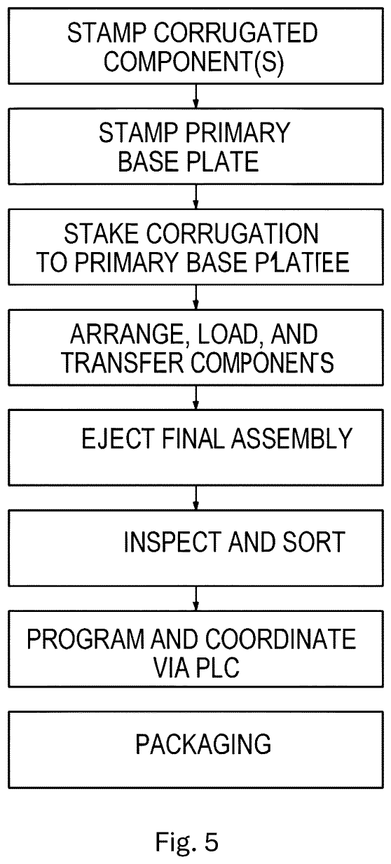

In operation an example process flow, as shown in FIG. 5, may include the following steps:
Stamp corrugated component(s) 12 in a punch press; inspect and sort non-compliant parts;
Stamp primary base plate 14 in a punch press; inspect and sort non-compliant parts;
Optionally stamp secondary base plate(s) 26 in a punch press; inspect and sort non-compliant parts;
Stake corrugation 12 to primary base plate 14 in a punch press; inspect and sort;
Optionally stake primary base plate 14 to secondary base plate 26 in a punch press; inspect and sort;
Arrange presses about a rotary table or along a conveyor with positioning fixtures; robots load components (corrugation first, then base plate[s]);
Eject final assembly; inspect and sort non-compliant assemblies;
Transfer compliant assemblies into packaging;
Program and coordinate presses, robots, rotary table/conveyor, and packaging via PLC; and
Place trays of assembled heat sinks into cartons for shipment.

Example non-limiting parameters may include sheet thickness (radiator): ˜0.2-1.2 mm (aluminum) or ˜0.1-0.8 mm (copper). Fin pitch: ˜1-5 mm; fin height: ˜5-25 mm; corrugation length: tailored to base plate width. Staking post preform: conic semi-pierced post; final mushroom head diameter ˜1.5-3× post shank diameter. Press tonnage: sized to material and geometry; progressive radiator forming may perform 4 bends/stroke (in-line) or 8 bends/stroke (perpendicular). Inspection: in-die or post-die aperture counting, camera-based bend count, stake head OD gauge.

Other aspects of the assembly may include, but are not limited to single-base, multi-corrugation stacks; multi-base, multi-corrugation assemblies (e.g., 2-base/3-radiator configuration). Vent patterns varied to tune airflow and pressure drop; mounting hole patterns integrated to reduce board-level assembly cost. Hybrid materials (copper radiator/aluminum base), surface treatments (anodize, nickel plate). Transfer topology: rotary index vs. linear conveyor; robotic or mechanical pick-and-place; optional AGV-assisted transfer. Joining: primary staking, with optional clinching or interference features; adhesives can be omitted or used only for vibration damping if desired.

The advantages of the this system and method may include increased surface area, the corrugated geometry can provide increased surface area at equal planform relative to die-cast or extruded fins, enabling higher convective performance for a given footprint. Further advantages include flexibility in material and weight, the use of thin sheet corrugations and elimination of loose fasteners/adhesives can reduce metal usage and mass. With respect to throughput and cost, progressive stamping and staking with hands-free automation reduces cycle time, labor, and secondary operations. With respect to stability, mushroomed staking provides vibration-resistant mechanical joints.

Those of ordinary skill in the art will understand and appreciate the aforementioned description of the invention has been made with reference to a certain exemplary embodiment of the invention, which describe a corrugated radiator heat sink and method of manufacture. Those of skill in the art will understand that obvious variations in construction, material, dimensions or properties may be made without departing from the scope of the invention which is intended to be limited only by the claims appended hereto.

1. A heat sink, comprising:
a corrugated radiator component stamped from sheet metal;
a primary base plate stamped from sheet metal; and
a plurality of staking joints that mechanically secure the corrugated radiator component to the primary base plate,
wherein each staking joint comprises a post formed in a base plate and a mushroom-shaped head produced by plastic deformation of the post to capture an adjacent component, and
wherein the corrugated radiator component includes vent apertures configured to promote omni-directional airflow through the corrugations.

2. The heat sink of claim 1, wherein the corrugated radiator component includes mounting apertures dimensioned to receive circuit-board fasteners.

3. The heat sink of claim 1, wherein the post is conical prior to staking and is produced by a semi-piercing operation in the base plate.

4. The heat sink of claim 1, wherein the corrugated radiator component comprises aluminum and at least one base plate comprises copper, or vice versa.

5. The heat sink of claim 1, wherein a secondary base plate is coupled to the primary base plate through the staking joint configured to stiffen the primary base plate and to distribute load from the staking joints.

6. The heat sink of claim 1, comprising two or more corrugated radiator components.

7. The heat sink of claim 1, wherein at least one of the radiator components includes optional fluid-passage apertures to accommodate a water pipe for active cooling.

8. The heat sink of claim 1, wherein the sheet metal of the corrugated radiator component is anodized aluminum or the sheet metal of at least one base plate is nickel-plated copper.

9. The heat sink of claim 1, wherein the staking joints are free of loose fasteners and adhesives.

10. A method of manufacturing a heat sink, comprising:
stamping, in a punch press, one or more corrugated radiator components from coil-fed sheet;
stamping a primary base plate from coil-fed sheet; and
staking the corrugated radiator component to the primary base plate in a punch press.

11. The method of claim 10, further comprising piercing vent apertures in the corrugated radiator component and piercing mounting apertures in at least one radiator component.

12. The method of claim 10, wherein staking comprises plastically deforming a conic post formed in a base plate to produce a mushroom-shaped head that captures the corrugated radiator component.

13. The method of claim 10, wherein stamping the corrugated radiator component includes progressively bending at least four corrugations per press stroke in-line with material feed or at least eight corrugations per press stroke perpendicular to material feed.

14. The method of claim 10, further comprising arranging a plurality of presses about a rotary table or along a conveyor and using pick-and-place robots to load components into positioning fixtures.

15. The method of claim 10, wherein a programmable logic controller (PLC) coordinates press activation, robotic transfer, inspection, and packaging.
